(19) United States
(12) Patent Application Publication
(10) Pub. No.: US 2002/0162068 A1
(43) Pub. Date: Oct. 31, 2002

(54) Weak data verification for low processing power devices

(76) Inventor: Jens Meggers, Marina del Rey, CA (US)

Correspondence Address: KNOBBE MARTENS OLSON & BEAR LLP, 2040 MAIN STREET, FOURTEENTH FLOOR, IRVINE, CA, 91614, US

(21) Appl. No.: 10/121,204

(22) Filed: Apr. 11, 2002

Related U.S. Application Data
(60) Provisional application No. 60/286,295, filed on Apr. 25, 2001.

(51) Int. Cl. H03M 13/00

(52) U.S. Cl. 714/758

(57) ABSTRACT

A system and associated methods check data before and after storage and/or transmission to provide a weak verification that the data has not been corrupted or manipulated. A data block is encoded to compress the data into a smaller size prior to storage for or transmission to a low processing power device, such as a personal digital assistant. A decoding process is subsequently performed on the low processing power device when the data is used. A known verification process is applied to verify only a proper subset of the compressed data. The known verification process is preferably a strong verification technique that ensures that certain critical portions of the encoded/compressed data are verified. Less critical portions of the encoded/compressed data are not checked since errors in these less critical portions may have an inconsequential effect on the use or processing of the data by the low processing power device.

### RELATED APPLICATIONS

This application claims the benefit of U.S. Provisional Application No. 60/286,295, filed on Apr. 25, 2001, which is hereby incorporated by reference.

### BACKGROUND OF THE INVENTION

1. Field of the Invention

The present invention relates generally to storage and transmission of electronic data, and more particularly, the invention relates to systems and methods for verifying data using low processing power computing devices.

2. Description of the Related Art

Most handheld computing devices, such as personal digital assistants (PDAs) or palmtop computers, are limited in terms of processing power and/or memory. It is frequently necessary to verify the integrity of a block of data, such as a file or transmitted packet, processed by such handheld devices to ensure that the data has not been corrupted or manipulated. Data processed by these devices can become corrupted, for example, as a result of errors in storage of the data. Data can also be unintentionally corrupted or maliciously manipulated, for example, when being transferred over a communication link such as the Internet and/or a wireless network. Errors can occur during transmission or a malicious intermediary can intercept and modify the data during transmission.

In order to detect data manipulation, existing systems typically utilize a deterministic algorithm or hash function (referred to as a data verification algorithm) to produce a digital signature or checksum (referred to as a check value). The data verification algorithm is applied to a block of data prior to and then after storage or transmission. The two check values, generated before and after, are compared and a match indicates that the data has likely not been corrupted. Typically, the entire block of data is processed to generate the check value, and therefore this approach consumes significant processing resources.

On handheld computing devices, applying deterministic algorithms or hashes to entire blocks of data to verify the integrity of the blocks can tax the limited computing capacities of these devices. The present invention seeks to address this problem among others.

### SUMMARY OF THE INVENTION

In accordance with one embodiment, a system and associated method are configured to check data before and after storage and/or transmission to provide a weak verification that the data has not been corrupted or manipulated. The check of the data after storage or transmission is preferably performed on a low processing power computing device, such as a PDA, mobile phone, or palmtop computer.

In one embodiment, a data block is encoded to compress the data into a smaller size prior to storage or transmission. A decoding process is subsequently performed on a low processing power device when the data is used. In accordance with a preferred embodiment, a known verification process is applied to verify only a proper subset of the compressed data. The known verification process is preferably a strong verification technique that ensures that certain critical portions of the encoded/compressed data are verified. Less critical portions of the encoded/compressed data are not checked since errors in these less critical portions may have an inconsequential effect on the use or processing of the data by the low processing power device. The result is that a weak verification scheme is effectively applied to the whole data block.

### BRIEF DESCRIPTION OF THE DRAWINGS

FIG. 1 depicts certain contexts in which a block of data can become corrupted prior to processing by a low processing power device.

FIG. 2 illustrates a method in accordance with one embodiment for verifying or checking data.

FIG. 3 illustrates a system configured to verify data on low processing power devices in accordance with one embodiment.

### DETAILED DESCRIPTION OF THE INVENTION

In the following description, reference is made to the accompanying drawings, which form a part hereof, and which show, by way of illustration, specific embodiments or processes in which the invention may be practiced. Where possible, the same reference numbers are used throughout the drawings to refer to the same or like components. In some instances, numerous specific details are set forth in order to provide a thorough understanding of the present invention. The present invention, however, may be practiced without the specific details or with certain alternative equivalent devices, components, and methods to those described herein. In other instances, well-known devices, components, and methods have not been described in detail so as not to unnecessarily obscure aspects of the present invention.

I. Data Corruption

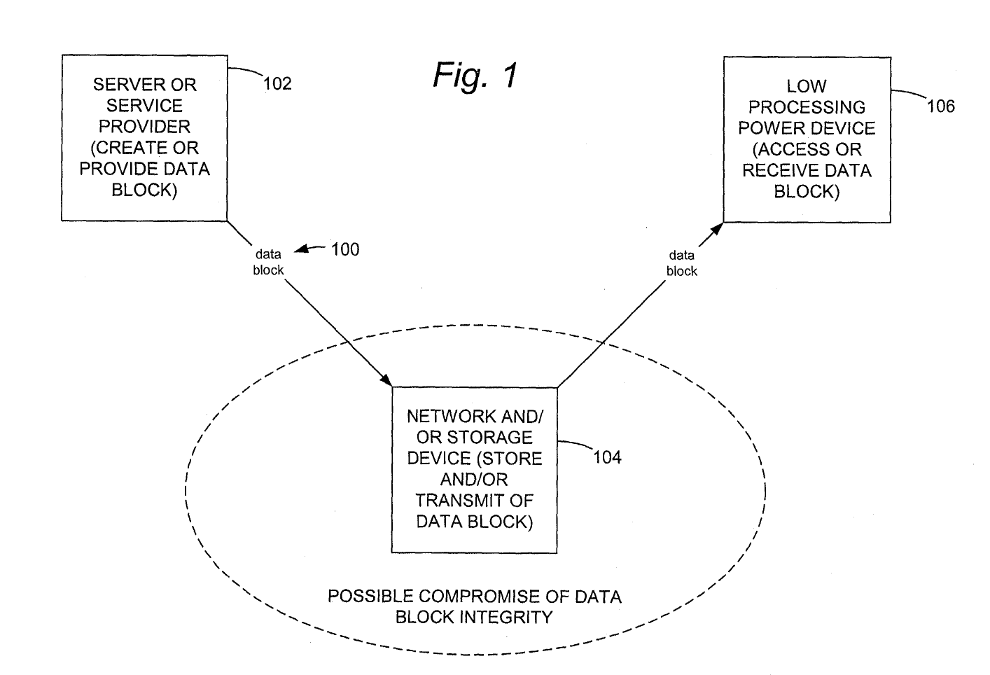

FIG. 1 depicts certain contexts in which a block of data 100 can become corrupted prior to processing by a low processing power device 106. The low processing power device 106 is preferably a portable or handheld device, such as a PDA or palmtop computer. The data block 100 can be any data that can be processed by the device 106, such as a text file, an image file, a network data packet, or a segment/frame of a video stream. The data block 100 is preferably created or provided by a server system, service provider, or content provider 102.

Before the low processing power device 106 can process the data block 100, the device 106 must access the data block 100. The access can be provided through a network or storage device 104. The network/storage device 104 can include, for example, a nonvolatile storage mechanism, a computer network/communication link or a combination of both. The nonvolatile storage mechanism can be, for example, a SmartMedia or CompactFlash card, a floppy disk, or a CD-ROM. The computer network can be, for example, the Internet, a wireless computer network, a USB cable/connection, or a combination thereof.

In one embodiment, a data block, such as an image, can be created by a content creator, and stored on a CD-ROM, which is then purchased by a user. The user then transfers the data block from the CD-ROM onto a PDA using a desktop computer connected to the PDA through a USB cable. During the transfer of the data block from the creator to the personal digital assistant, there are many opportunities where the data block can become corrupted. Errors can occur in the storage or transmission of the data block in any of the steps of the process of transferring the data to the personal digital assistant. These opportunities for corruption are indicated by the dotted ellipse surrounding the network/storage device 104.

In another embodiment, a content provider can provide data blocks to wireless-enabled PDAs through the Internet and a wireless network. It may be the case that critical or sensitive data is being provided by the content provider. While the data is transmitted through the Internet and the wireless network, a malicious intermediary can intercept the data blocks, modify the data, and send the modified data blocks on to the recipient. Alternatively, unintentional data corruption can occur through errors in transmission. These opportunities are also indicated by the dotted ellipse surrounding the network/storage device 104 in FIG. 1.

II. Weak Data Verification Scheme

In accordance with one embodiment, a weak data verification scheme is used to check data blocks processed by a low processing power device. As opposed to a strong data verification scheme, which can provide strong assurances that a data block has not been altered or corrupted during storage or transmission, the weak data verification scheme provides only weak or moderate assurances. The weak data verification scheme, however, requires substantially less processing than a strong data verification scheme.

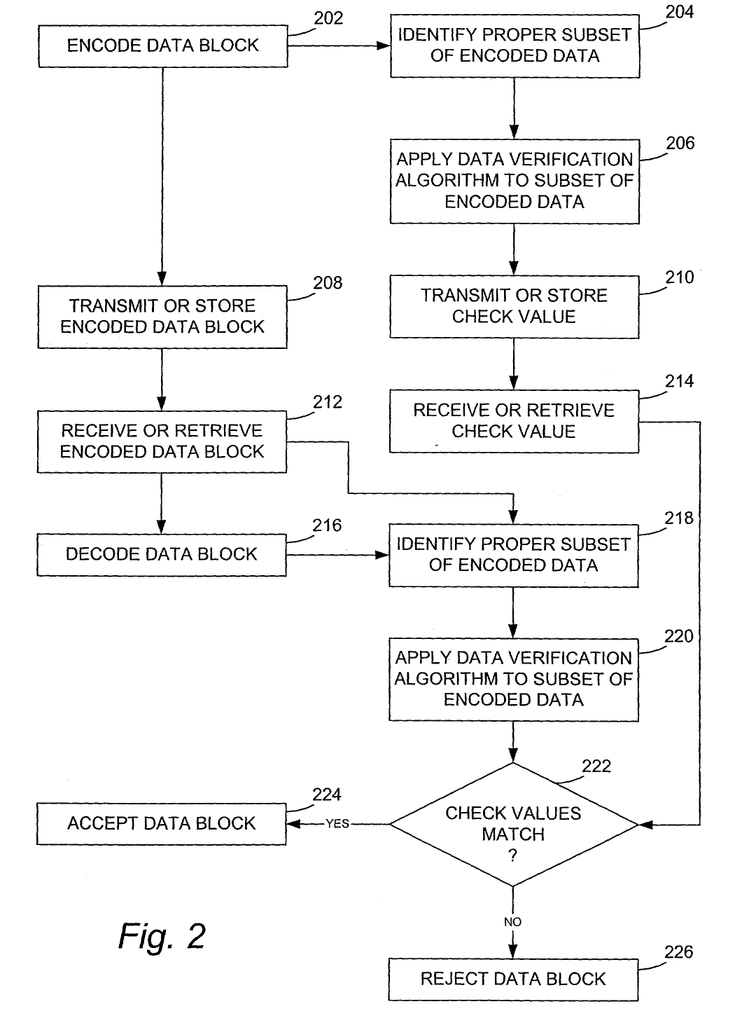

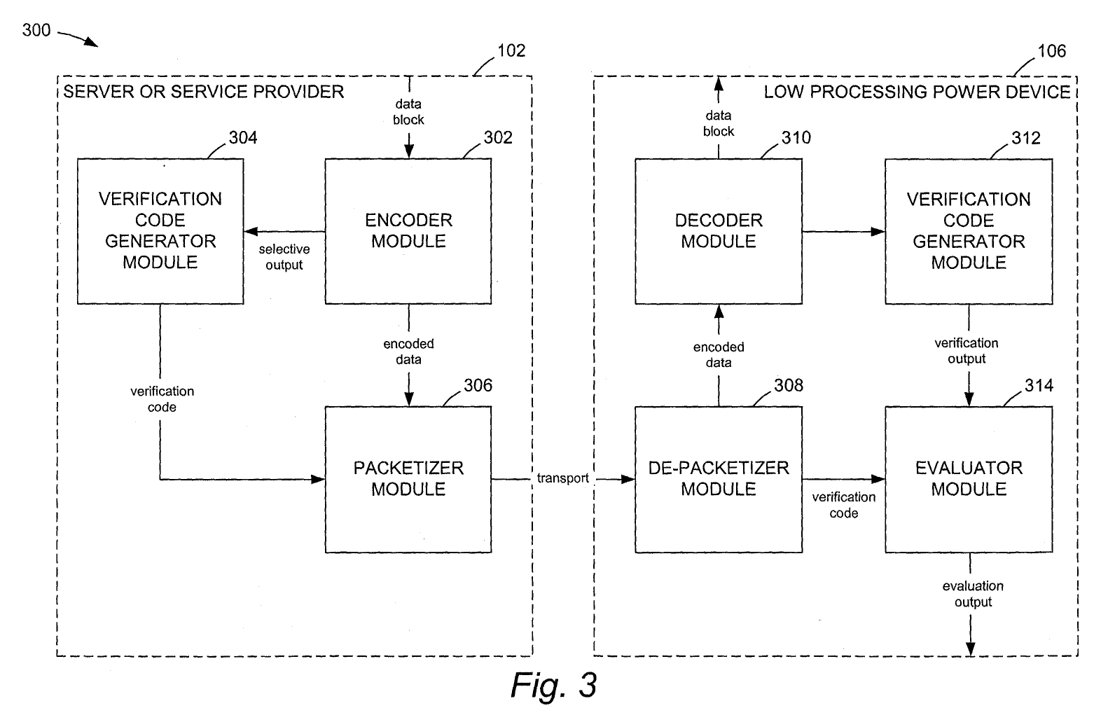

FIG. 2 illustrates a method 200 in accordance with one embodiment for verifying or checking data. FIG. 3 illustrates a system 300 configured to verify data on low processing power devices in accordance with one embodiment. The method 200 is described in general in the following paragraph. The method 200 is then described step-by-step in the subsequent paragraphs in conjunction with the system 300. Certain steps of the method 200 will be described in additional detail in the subsections that follow.

In the method 200, a data block is encoded to compress the data into a smaller size prior to storage or transmission. A decoding process is subsequently performed on a low processing power device when the data is used. In accordance with a preferred embodiment, a known verification process is applied to verify only a proper subset of the compressed data. The known verification process is preferably a strong verification technique that ensures that certain critical portions of the encoded/compressed data are verified. Less critical portions of the encoded/compressed data are not checked since errors in these less critical portions may have an inconsequential effect on the use or processing of the data by the low processing power device. The result is that a weak verification scheme is effectively applied to the whole data block.

At a step 202 of the method 200, a data block is encoded, preferably to compress the data block into a smaller size for storage or transmission. Referring to FIG. 3, the data block is preferably encoded by the server or service provider 102 using an encoder module 302. Any of many known compression techniques, such as dictionary-based compression, can be used to encode the data. One example of dictionary-based compression is discussed in greater detail is Subsection II.A, below.

At a step 204, a proper subset of the encoded data is identified. As will be discussed below, the proper subset is preferably length data produced by a dictionary-based encoding process. Identification of the proper subset will be discussed in additional detail in Subsection II.B, below. The step 204 is preferably performed by the encoder module 302.

At a step 206, a data verification algorithm is applied to the identified subset of the encoded data. The verification algorithm preferably produces a check value based upon which the data block can be subsequently verified. The data verification algorithm is preferably a known algorithm such as, for example, a standard CRC function like CRC32 or CRC16, or a hash function like MD5. Referring to FIG. 3, the verification algorithm of the step 206 is preferably embodied in a verification code generator module 304.

At a step 208, the encoded data block is transmitted or stored for subsequent access by the low processing power device. As discussed above with reference to FIG. 1, data can be transferred from a server or a service provider by storage on a transferable medium and/or transmission through a communication network.

At a step 210, the check value is also transmitted or stored for subsequent access by the low processing power device. In one embodiment, the check value is transmitted or stored in conjunction with the encoded data block, preferably by appending the check value to the data block. Alternatively, the check value is transmitted or stored separate from the encoded data block. By transmitting or storing the check value separately, the check value can also be used as a verifying signature of the data originally created or provided by the service or service provider.

Referring to FIG. 3, the steps 208 and 210 are preferably performed by a packetizer module 306. The packetizer module 306 preferably breaks the data block up into packets for transmission over a computer network to a low processing power device 106.

At a step 212, the encoded data block is received or retrieved by the low processing power device. At a step 214, the check value is also received or retrieved by the low processing power device. As discussed with reference to the step 208 and 210, the check value can received or retrieved in conjunction with or separate from the encoded data block.

Referring to FIG. 3, the steps 212 and 214 are preferably performed by a de-packetizer module 308. The de-packetizer module 308 preferably receives data packets and reassembles the packets into a compressed data block on the power device 106.

At a step 216, the encoded data block is decoded or decompressed by the low processing power device. Referring to FIG. 3, the step 216 is preferably performed by a decoder module 310 on the low processing power device 106.

At a step 218, the proper subset of the encoded data block is identified by the low processing power device. In one embodiment, as indicated by the connection between the decoding step 216 and the identification step 218, the proper subset can be identified in conjunction with or after decoding, preferably by configuring a decoding module to output the identified data. In this case, the step 218 is preferably performed by the decoder module 310. In one embodiment, the identification step 218 is performed in parallel or before the decoding step 216 by accessing the encoded data block. In this case, the step 218 can be performed by the de-packetizer module 308 or the decoder module 310.

At a step 220, the low processing power device applies the data verification algorithm to the identified subset of the received or retrieved data block to produce a second check value. The verification algorithm of the step 220 is preferably embodied in a verification code generator module 312 on the low processing power device.

At a step 222, the received or retrieved check value is compared to the second check value. At a step 224, if the two check values match, the data block is accepted as verified. On the other hand, at a step 226, if the two check values don't match, the data block is rejected as corrupted or compromised. The steps 222, 224, and 226 are preferably performed by an evaluator module 314 on the low processing power device.

As will be understood by one skilled in the art, the modules 302-314 referred to in FIG. 3 can represent software, hardware, components, devices, or systems. These modules can include, for example, programs or code sections or appropriately configured computer circuits. such as devices.

A. Dictionary-Based Compression

Dictionary-based compression techniques compress data by finding repeating or well-known patterns in a data sequence. Most dictionary-based compression schemes that are configured to be applied to unknown data use the data stream itself as the dictionary.

In one embodiment, a data block is coded into (a) literals and (b) matches to previously encoded data. A literal is preferably includes sequence of characters or data and the length of the sequence. A match preferably includes a match indicator and a match length. The match indicator is an offset from the present position indicating where in the previously encoded data a matching sequence is located. The match length indicates the length of the matching sequence in the previously encoded data. For example, the data block

ABCABCABC

can be encoded as follows:

literal: ABC, length 3

match: offset -3, length 3

match: offset -3, length 3

This encoded literal/match sequence is not unique and the different literal/match sequences can be produced by different implementations. For example, this same data block can also be encoded as follows:

literal: A, length 1

literal: BC, length 2

match: offset -3, length 2

literal: C, length 1

match: offset -3, length 3

B. Identifying a Subset of Data to be Verified

Preferably, the proper subset of the encoded data to which a verification process is applied includes only a minor portion of all of the encoded data, such as less than 1%, 2%, 5%, 10%, 20%, or 40% of the encoded data. By including only a small portion of the encoded data in the subset, the overhead of applying a data verification process to the majority of the encoded data is avoided. Although up to 50% or more of the data can be identified, the savings in processing to be performed by the low processing power device decreases as proportionally more of the encoded data is included in the subset of data to be verified. Preferably, the identified subset includes encoded data that is more essential or critical in decoding the encoded data than the data that is not identified.

In accordance with one embodiment, the proper subset includes the sequence of lengths of each of the match or literal elements. For example, in the first and second examples presented above, the sequences of lengths are (3, 3, 3) and (1, 2, 2, 1, 3) respectively.

In practice, for typical dictionary-based compression schemes, the length data represents about 5% of a compressed block of data. Although data corruption can occur in parts of the compressed data block other than the length data, for certain types of data, as long as the integrity of the length data is maintained the data block will likely be able to be processed successfully. Furthermore, any substantial corruption or manipulation of the data will also likely result in corruption of the length data.

In the case of image files, for example, as long as the integrity of the length data is maintained, the image file will likely be able to be decoded successfully. Although corruption of literals and offsets may be present in a compressed file, these types of corruption will likely only result in minor imperfections in the decoded image as long as the integrity of the length data is maintained.

As discussed above, different encoding implementations will typically generate different encoded representations. Accordingly, if a data file is maliciously decoded and again encoded by an intermediary, the length data of the encoded data block will not be consistent with the check value crated from the original length data. Accordingly, the decoding and re-encoding of a data block by an intermediary can be detected by checking the length data against the original check value.

III. Conclusion

Although the invention has been described in terms of certain embodiments, other embodiments that will be apparent to those of ordinary skill in the art, including embodiments which do not provide all of the features and advantages set forth herein, are also within the scope of this invention. Accordingly, the scope of the invention is defined by the claims that follow. In the claims, the term “based upon” shall include situations in which a factor is taken into account directly and/or indirectly, and possibly in conjunction with other factors, in producing a result or effect. In method claims, reference characters are used for convenience of description only, and do not indicate a particular order for performing a method.

What is claimed is:

1. A method of checking validity a data block on a low processing power computing device, the method comprising:
accessing an encoded representation of the data block;
identifying a proper subset of the encoded representation;
performing a validity check on the proper subset; and
using the validity check of the proper subset of the encoded representation of the data block as an indication of the validity of the data block.

2. The method of claim 1, wherein the encoded representation is a dictionary-based compressed representation comprising length data.

3. The method of claim 2, wherein the proper subset comprises the length data.

4. The method of claim 2, wherein the proper subset consists of the length data.

5. The method of claim 2, wherein the proper subset consists essentially of the length data.

6. The method of claim 1, wherein the low processing power computing device is a personal digital assistant.

7. The method of claim 1, wherein the low processing power computing device is a palmtop computer.

8. A method of reducing a quantity of processing performed by a low processing power computing device in checking validity of a data block accessed by the device, the method comprising:
encoding the data block to created and encoded representation of the data block;
storing or transmitting the encoded representation of the data block to provide access to the data block to the low processing power computing device;
accessing a encoded representation of a the data block on the low processing power computing device;
identifying a proper subset of the encoded representation on the low processing power computing device;
performing a validity check on the proper subset on the low processing power computing device; and
using the validity check of the proper subset of the encoded representation of the data block as an indication of the validity of the data block on the low processing power computing device.

9. The method of claim 8, wherein the compressed representation is a dictionary-based compressed representation comprising length data.

10. The method of claim 9, wherein the proper subset comprises the length data.

11. The method of claim 9, wherein the proper subset consists of the length data.

12. The method of claim 9, wherein the proper subset consists essentially of the length data.
